(19) United States
(12) Patent Application Publication
(10) Pub. No.: US 2015/0325545 A1
(43) Pub. Date: Nov. 12, 2015

(54) PACKAGE STRUCTURE, CHIP STRUCTURE AND FABRICATION METHOD THEREOF

(71) Applicant: Siliconware Precision Industries Co., Ltd., Taichung (TW)

(72) Inventors: Jyun-Ling Tsai, Taichung (TW); Chang-Lun Lu, Taichung (TW)

(21) Appl. No.: 14/689,140

(22) Filed: Apr. 17, 2015

(30) Foreign Application Priority Data
May 9, 2014 (TW) 103116498

(51) Int. Cl. H01L 23/00; H01L 21/48; H01L 23/498

(52) U.S. Cl. CPC H01L 24/14; H01L 23/498; H01L 23/49811; H01L 21/4846; H01L 2224/145; H01L 2224/1405

(57) ABSTRACT

A chip structure is provided, which includes: a substrate having a plurality of conductive pads formed on a surface thereof; a first copper layer formed on each of the conductive pads; a nickel layer formed on the first copper layer; a second copper layer formed on the nickel layer; and a tin layer formed on the second copper layer, thereby effectively reducing stresses.

### BACKGROUND OF THE INVENTION

1. Field of the Invention The present invention relates to package structures, chip structures and fabrication methods thereof, and more particularly, to a package structure having conductive posts, a chip structure and a fabrication method thereof.

2. Description of Related Art

Flip-chip technologies facilitate to reduce chip packaging sizes and shorten signal transmission paths and therefore have been widely used for chip packaging. Various types of packages such as chip scale packages (CSPs), direct chip attached (DCA) packages and multi-chip module (MCM) packages can be achieved through flip-chip technologies.

In a flip-chip packaging process, a big CTE (Coefficient of Thermal Expansion) mismatch between a chip and a packaging substrate adversely affects the formation of joints between conductive bumps of the chip and contacts of the packaging substrate, thus easily resulting in delamination of the conductive bumps from the packaging substrate. On the other hand, along with increased integration of integrated circuits, the CTE mismatch between the chip and the packaging substrate induces more thermal stresses and leads to more serious warpage, thereby reducing the product reliability and resulting in failure of a reliability test.

Accordingly, a silicon interposer is disposed between the packaging substrate and the semiconductor chip. Since the silicon interposer is close in material to the semiconductor chip, the above-described drawbacks caused by a CTE mismatch can be effectively overcome.

FIG. 1 is a schematic cross-sectional view of a conventional package structure having a silicon interposer. Such a package structure overcomes the above-described drawbacks. In addition, compared with a package structure having a semiconductor chip directly disposed on a packaging substrate, the package structure of FIG. 1 has a reduced layout area.

For example, a packaging substrate generally has a minimum line width/pitch of 12/12 um. When the I/O count of a semiconductor chip increases, since the line width/pitch of the packaging substrate cannot be reduced, the area of the packaging substrate must be increased such that more circuits can be formed on the packaging substrate and electrically connected to the semiconductor chip having high I/O count. On the other hand, referring to FIG. 1, a plurality of semiconductor chips 11 are disposed on a silicon interposer 12 having through silicon vias (TSVs) and the silicon interposer 12 is further disposed on a packaging substrate 13. As such, the semiconductor chips 11 are electrically connected to the packaging substrate 13 through the silicon interposer 12. Through a semiconductor process, the silicon interposer 12 can have a line width/pitch of 3/3 um or less. Therefore, the semiconductor chips 11 having high I/O counts can be disposed on the through silicon interposer 2 without the need to increase the area of the packaging substrate 13. Further, the fine line width/pitch of the silicon interposer 12 facilitates to shorten the electrical transmission path. Therefore, compared with semiconductor chips directly disposed on a packaging substrate, the semiconductor chips 11 disposed on the silicon interposer 12 can achieve a higher electrical transmission speed (efficiency).

FIG. 1B is a schematic cross-sectional view of a bump interconnection structure between the semiconductor chip 11 and the silicon interposer 12 of a conventional package structure. Referring to FIG. 1B, a first copper layer 112, a first nickel layer 113 and a first tin layer 114 are sequentially formed on an electrode pad 111 of the semiconductor chip 11, and a second copper layer 121, a second nickel layer 122 and a second tin layer 123 are sequentially formed on the silicon interposer 12. Further, the first tin layer 114 of the semiconductor chip 11 is bonded to the second tin layer 123 of the silicon interposer 12.

However, during thermal cycles, the tin layers and the nickel layers of the fine-pitch bump interconnection structure easily react with one another to form an intermetallic compound 115, 124 of Ni₃Sn₄. Since the intermetallic compound 115, 124 of Ni₃Sn₄ is hard, brittle and easy to crack, the product reliability is reduced.

Therefore, how to overcome the above-described drawbacks has become critical.

### SUMMARY OF THE INVENTION

In view of the above-described drawbacks, the present invention provides a chip structure, which comprises: a substrate having a plurality of conductive pads formed on a surface thereof; a first copper layer formed on each of the conductive pads; a nickel layer formed on the first copper layer; a second copper layer formed on the nickel layer; and a tin layer formed on the second copper layer.

In the above-described chip structure, the substrate can be an active chip, a passive chip or an interposer. The first copper layer can have a wide bottom and a narrow top.

The above-described chip structure can further comprise a UBM (Under Bump Metallurgy) layer formed between each of the conductive pads and the first copper layer. The above-described chip structure can further comprise a Cu₆Sn₅ layer formed between the second copper layer and the tin layer.

The present invention further provides a method for fabricating a chip structure, which comprises the steps of: providing a substrate having a plurality of conductive pads formed on a surface thereof and forming a resist layer on the substrate, wherein the resist layer has a plurality of openings formed corresponding in position to the conductive pads, respectively; sequentially forming a first copper layer, a nickel layer, a second copper layer and a tin layer in each of the openings of the resist layer; and removing the resist layer.

In an embodiment, the conductive pads are exposed from the openings of the resist layer, respectively, and the first copper layer is formed on each of the conductive pads.

In the above-described method, the substrate can be an active chip, a passive chip or an interposer. Each of the openings of the resist layer can have a wide bottom and a narrow top so as to cause the first copper layer formed in the opening to have a wide bottom and a narrow top.

In an embodiment, before forming the resist layer, the method further comprises forming a UBM layer on the surface of the substrate, thereby allowing the UBM layer to be sandwiched between the first copper layer and the conductive pads. After removing the resist layer, the method further comprises removing the UBM layer under the resist layer.

The above-described method can further comprise forming a Cu₆Sn₅ layer between the second copper layer and the tin layer.

The present invention further provides a package structure, which comprises: a carrier having a plurality of conductive posts formed on a surface thereof; and a chip structure, comprising: a substrate having a plurality of conductive pads formed on a surface thereof; a first copper layer formed on each of the conductive pads; a first nickel layer formed on the first copper layer; a second copper layer formed on the first nickel layer; and a first tin layer formed on the second copper layer, wherein the chip structure is disposed on the conductive posts through the first tin layer.

In the above-described package structure, the substrate can be an active chip, a passive chip or an interposer. The first copper layer can have a wide bottom and a narrow top. The above-described package structure can further comprise a UBM layer formed between each of the conductive pads and the first copper layer.

The above-described package structure can further comprise a Cu₆Sn₅ layer formed between the second copper layer and the first tin layer. Each of the conductive posts can comprise a third copper layer, a second nickel layer and a second tin layer sequentially formed on the surface of the carrier. The package structure can further comprise a Ni₃Sn₄ layer formed between the second nickel layer and the second tin layer.

In the above-described package structure, each of the conductive posts can comprise a third copper layer, a second nickel layer, a fourth copper layer and a second tin layer sequentially formed on the surface of the carrier. The package structure can further comprise a Cu₆Sn₅ layer formed between the fourth copper layer and the second tin layer. The carrier can be an active chip, a passive chip, an interposer, a packing substrate or a circuit board.

According to the present invention, a Cu₆Sn₅ layer is formed at at least one side of the tin layer. Since Cu₆Sn₅ is softer and lower in rigidity than Ni₃Sn₄, stresses can be absorbed by the Cu₆Sn₅ layer, thereby improving the product yield.

### BRIEF DESCRIPTION OF DRAWINGS

FIG. 1A is a schematic cross-sectional view of a conventional package structure having a silicon interposer;

FIG. 1B is a schematic cross-sectional view of a bump interconnection structure between the semiconductor chip and the silicon interposer of a conventional package structure;

FIGS. 2A to 2D are schematic cross-sectional views showing a method for fabricating a chip structure according to the present invention; and

FIGS. 3A and 3B are schematic cross-sectional views showing different embodiments of a package structure of the present invention.

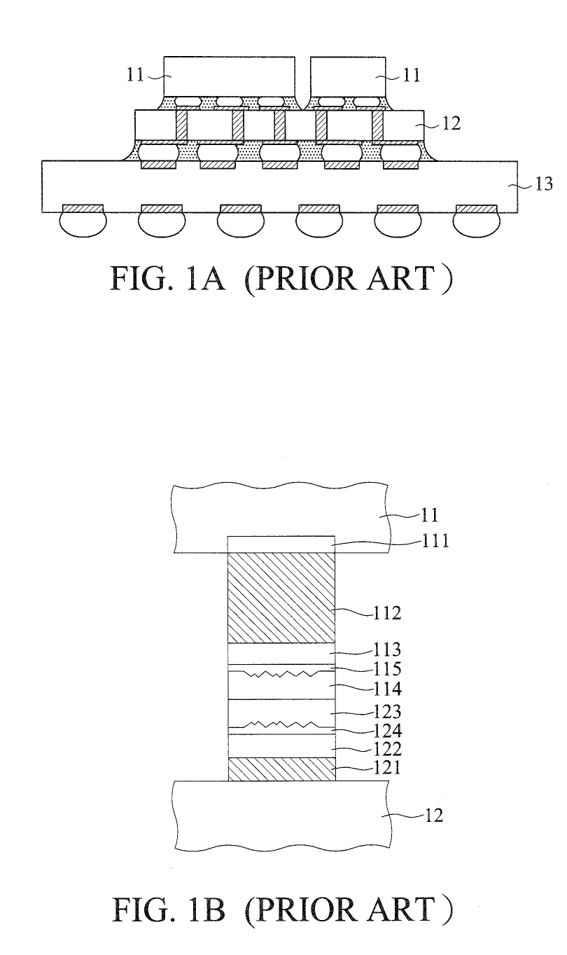

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms in the present specification are merely for illustrative purposes and should not be construed to limit the scope of the present invention.

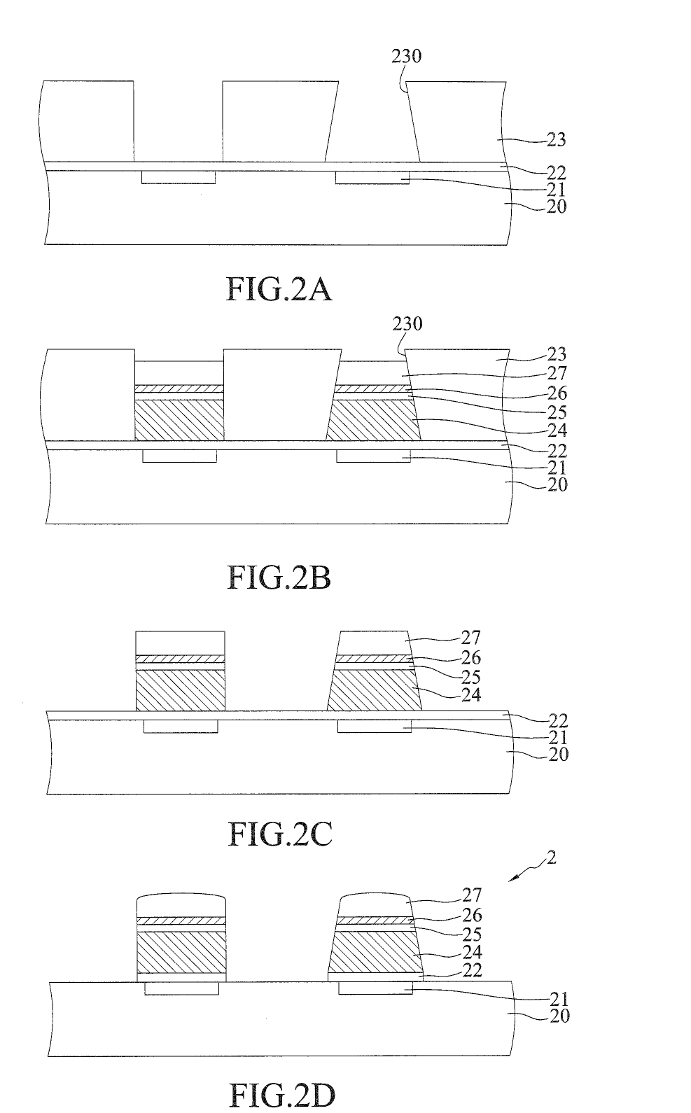

FIGS. 2A to 2D are schematic cross-sectional views showing a method for fabricating a chip structure according to the present invention.

Referring to FIG. 2A, a substrate 20 having a plurality of conductive pads 21 formed on a surface thereof is provided, and a UBM layer (Under Bump Metallurgy) 22 is formed on the surface of the substrate 20. A resist layer 23 is formed on the UBM layer 22, and a plurality of openings 230 are formed in the resist layer 23 corresponding in position to the conductive pads 21, respectively. The substrate 20 is an active chip, a passive chip or an interposer. A portion of the openings 230 of the resist layer 23 have a wide bottom and a narrow top. In another embodiment, the UBM layer 22 is omitted and the resist layer 23 is directly formed on the substrate 20, and the conductive pads 21 are exposed from the openings 230 of the resist layer 23.

Referring to FIG. 2B, a first copper layer 24, a nickel layer 25, a second copper layer 26 and a tin layer 27 are sequentially formed in each of the openings 230 of the resist layer 23. For each of the openings 230 having a wide bottom and a narrow top, the first copper layer 24 formed in the opening 230 also has a wide bottom and a narrow top. In the case the resist layer 23 is directly formed on the substrate 20 and the conductive pads 21 are exposed from the openings 230 of the resist layer 23, the first copper layer 24 is formed on each of the conductive pads 21.

Referring to FIG. 2C, the resist layer 23 is removed.

Referring to FIG. 2D, the UBM layer 22 under the resist layer 23 is removed. If needed, a reflow process can be performed. As such, a chip structure 2 is obtained.

In another embodiment, a patterned UBM layer 22 is formed before formation of the resist layer 23. As such, the process of removing the UBM layer 22 under the resist layer 23 as described in FIG. 2D is dispensed with.

Further, a Cu₆Sn₅ layer (not shown) can be formed between the second copper layer 26 and the tin layer 27.

The present invention further provides a chip structure, which has: a substrate 20 having a plurality of conductive pads 21 formed on a surface thereof; a first copper layer 24 formed on each of the conductive pads 21; a nickel layer 25 formed on the first copper layer 24; a second copper layer 26 formed on the nickel layer 25; and a tin layer 27 formed on the second copper layer 26.

In the above-described chip structure, the substrate 20 can be an active chip, a passive chip or an interposer. The first copper layer 24 can have a wide bottom and a narrow top.

The above-described chip structure can further have a UBM layer 22 formed between each of the conductive pads 21 and the first copper layer 24. The above-described chip structure can further have a Cu₆Sn₅ layer (not shown) formed between the second copper layer 26 and the tin layer 27.

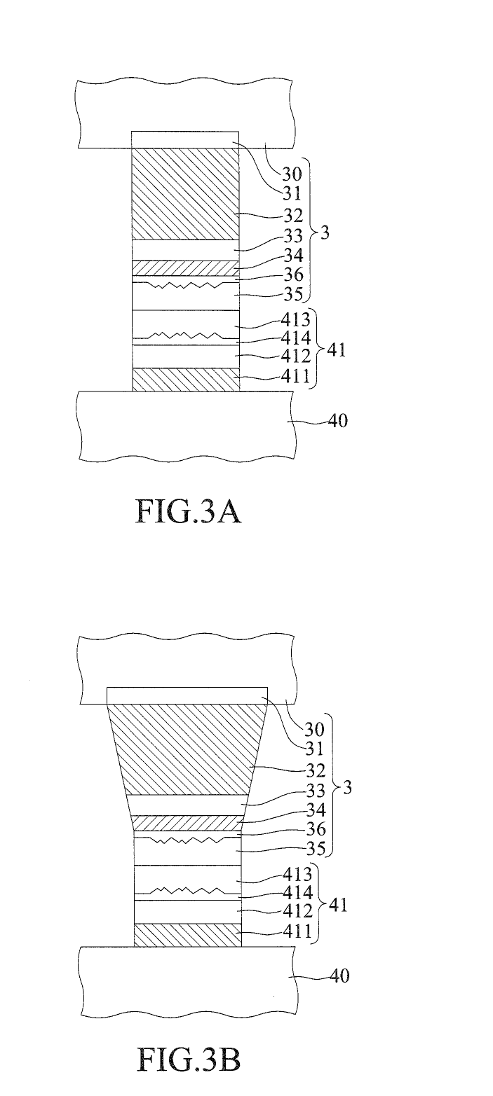

FIGS. 3A and 3B are schematic cross-sectional views showing different embodiments of a package structure of the present invention. Referring to FIGS. 3A and 3B, a carrier 40 having a plurality of conductive posts 41 formed on a surface thereof is provided, and a chip structure 3 is disposed on the conductive posts 41 of the carrier 40. In particular, referring to FIG. 3A, a chip structure 3 having a plurality of bumps having a cylindrical shape as in FIG. 2D is disposed on the conductive posts 41 of the carrier 40, and referring to FIG. 3B, a chip structure 3 having a plurality of bumps having a wide bottom and a narrow top as in FIG. 2D is disposed on the conductive posts 41 of the carrier 40. The chip structure 3 has: a substrate 30 having a plurality of conductive pads 31 formed on a surface thereof; a first copper layer 32 formed on each of the conductive pads 31; a first nickel layer 33 formed on the first copper layer 32; a second copper layer 34 formed on the first nickel layer 33; and a first tin layer 35 formed on the second copper layer 34. The chip structure 3 is disposed on the conductive posts 41 of the carrier 40 through the first tin layer 35.

The substrate 30 can be an active chip, a passive chip or an interposer. The first copper layer 32 can have a wide bottom and a narrow top. Further, a UBM layer (not shown) can be formed between each of the conductive pads 31 and the first copper layer 32.

The package structure can further have a Cu₆Sn₅ layer 36 formed between the second copper layer 34 and the first tin layer 35. Each of the conductive posts 41 can have a third copper layer 411, a second nickel layer 412 and a second tin layer 413 sequentially formed on the surface of the carrier 40. Further, a Ni₃Sn₄ layer can be formed between the second nickel layer 412 and the second tin layer 413.

Alternatively, each of the conductive posts 41 can have a third copper layer, a second nickel layer, a fourth copper layer and a second tin layer (not shown) sequentially formed on the surface of the carrier 40. Further, a Cu₆Sn₅ layer (not shown) can be formed between the fourth copper layer and the second tin layer. The carrier 40 can be an active chip, a passive chip, an interposer, a packaging substrate or a circuit board.

Compared with the conventional Ni₃Sn₄ layers formed at upper and lower sides of a tin layer, a Cu₆Sn₅ layer is formed at at least one side of the tin layer in the present invention. Since Cu₆Sn₅ is softer and lower in rigidity than Ni₃Sn₄, stresses can be absorbed by the Cu₆Sn₅ layer, thereby improving the product yield. Further, the copper layer close to each of the conductive pads can have a wide bottom and a narrow top so as to strengthen its bonding with the conductive pad or the UBM layer and reduce stresses.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A chip structure, comprising:
a substrate having a plurality of conductive pads formed on a surface thereof;
a first copper layer formed on each of the conductive pads;
a nickel layer formed on the first copper layer;
a second copper layer formed on the nickel layer; and
a tin layer formed on the second copper layer.

2. The structure of claim 1, wherein the substrate is an active chip, a passive chip or an interposer.

3. The structure of claim 1, wherein the first copper layer has a wide bottom and a narrow top.

4. The structure of claim 1, further comprising a UBM (Under Bump Metallurgy) layer formed between each of the conductive pads and the first copper layer.

5. The structure of claim 1, further comprising a Cu₆Sn₅ layer formed between the second copper layer and the tin layer.

6. A method for fabricating a chip structure, comprising the steps of:
providing a substrate having a plurality of conductive pads formed on a surface thereof and forming a resist layer on the substrate, wherein the resist layer has a plurality of openings formed corresponding in position to the conductive pads, respectively;
sequentially forming a first copper layer, a nickel layer, a second copper layer and a tin layer in each of the openings of the resist layer; and
removing the resist layer.

7. The method of claim 6, wherein the conductive pads are exposed from the openings of the resist layer, respectively, and the first copper layer is formed on each of the conductive pads.

8. The method of claim 6, wherein the substrate is an active chip, a passive chip or an interposer.

9. The method of claim 6, wherein each of the openings has a wide bottom and a narrow top so as to cause the first copper layer formed in the opening to have a wide bottom and a narrow top.

10. The method of claim 6, before forming the resist layer, further comprising forming a UBM layer on the surface of the substrate, thereby allowing the UBM layer to be sandwiched between the first copper layer and the conductive pads.

11. The method of claim 10, after removing the resist layer, further comprising removing the UBM layer under the resist layer.

12. The method of claim 6, further comprising forming a Cu₆Sn₅ layer between the second copper layer and the tin layer.

13. A package structure, comprising:
a carrier having a plurality of conductive posts formed on a surface thereof; and
a chip structure, comprising:
a substrate having a plurality of conductive pads formed on a surface thereof;
a first copper layer formed on each of the conductive pads;
a first nickel layer formed on the first copper layer;
a second copper layer formed on the first nickel layer; and
a first tin layer formed on the second copper layer, wherein the chip structure is disposed on the conductive posts through the first tin layer.

14. The structure of claim 13, wherein the substrate is an active chip, a passive chip or an interposer.

15. The structure of claim 13, wherein the first copper layer has a wide bottom and a narrow top.

16. The structure of claim 13, further comprising a UBM layer formed between each of the conductive pads and the first copper layer.

17. The structure of claim 13, further comprising a Cu₆Sn₅ layer formed between the second copper layer and the first tin layer.

18. The structure of claim 13, wherein each of the conductive posts comprises a third copper layer, a second nickel layer and a second tin layer sequentially formed on the surface of the carrier.

19. The structure of claim 18, further comprising a Ni₃Sn₄ layer formed between the second nickel layer and the second tin layer.

20. The structure of claim 13, wherein each of the conductive posts comprises a third copper layer, a second nickel layer, a fourth copper layer and a second tin layer sequentially formed on the surface of the carrier.

21. The structure of claim 20, further comprising a Cu₆Sn₅ layer formed between the fourth copper layer and the second tin layer.

22. The structure of claim 13, wherein the carrier is an active chip, a passive chip, an interposer, a packing substrate or a circuit board.
